(19) United States
(12) Patent Application Publication
(10) Pub. No.: US 2017/0194430 A1
(43) Pub. Date: Jul. 6, 2017

(54) METHOD FOR FABRICATING NANOWIRES FOR HORIZONTAL GATE ALL AROUND DEVICES FOR SEMICONDUCTOR APPLICATIONS

(71) Applicant: Applied Materials, Inc., Santa Clara, CA (US)

(72) Inventors: Bingxi Sun WOOD, Cupertino, CA (US); Michael G. WARD, Niskayuna, NY (US); Shiyu SUN, Santa Clara, CA (US); Michael CHUDZIK, Mountain View, CA (US); Nam Sung KIM, Sunnyvale, CA (US); Hua CHUNG, San Jose, CA (US); Yi-Chiau HUANG, Fremont, CA (US); Chentsau YING, Cupertino, CA (US); Ying ZHANG, Santa Clara, CA (US); Chi-Nung NI, Foster City, CA (US); Lin DONG, San Jose, CA (US); Dongqing YANG, Pleasanton, CA (US)

(21) Appl. No.: 15/395,928

(22) Filed: Dec. 30, 2016

Related U.S. Application Data
(60) Provisional application No. 62/275,083, filed on Jan. 5, 2016.

(51) Int. Cl. H01L 29/06; H01L 21/02; H01L 29/66; H01L 21/311; H01L 21/764; H01L 21/306; H01L 29/423

(52) U.S. Cl. CPC H01L 29/0673; H01L 21/30604; H01L 21/0228; H01L 29/42392; H01L 21/02115; H01L 21/31111; H01L 21/764; H01L 29/0649; H01L 29/66795; H01L 29/66742; H01L 21/0214; H01L 21/0217; H01L 21/02126; H01L 21/02532; H01L 21/0262

(57) ABSTRACT

The present disclosure provides methods for forming nanowire spacers for nanowire structures with desired materials in horizontal gate-all-around (hGAA) structures for semiconductor chips. In one example, a method of forming nanowire spaces for nanowire structures on a substrate includes performing a lateral etching process on a substrate having a multi-material layer disposed thereon, wherein the multi-material layer including repeating pairs of a first layer and a second layer, the first and second layers each having a first sidewall and a second sidewall respectively exposed in the multi-material layer, wherein the lateral etching process predominately etches the second layer through the second layer forming a recess in the second layer, filling the recess with a dielectric material, and removing the dielectric layer over filled from the recess.

### CROSS-REFERENCE TO RELATED APPLICATIONS

This application claims benefit of U.S. Provisional Application Ser. No. 62/275,083 filed Jan. 5, 2016 (Attorney Docket No. APPM/23559L), which is incorporated by reference in its entirety.

### BACKGROUND

Field

Embodiments of the present invention generally relate to methods for forming vertically stacked nanowires with desired materials on a semiconductor substrate, and more particularly to methods for forming vertically stacked nanowires on a semiconductor substrate with desired materials for three dimensional semiconductor manufacturing applications.

Description of the Related Art

Reliably producing sub-half micron and smaller features is one of the key technology challenges for next generation very large scale integration (VLSI) and ultra large-scale integration (ULSI) of semiconductor devices. However, as the limits of circuit technology are pushed, the shrinking dimensions of VLSI and ULSI technology have placed additional demands on processing capabilities. Reliable formation of gate structures on the substrate is important to VLSI and ULSI success and to the continued effort to increase circuit density and quality of individual substrates and die.

As circuit densities increase for next generation devices, the widths of interconnects, such as vias, trenches, contacts, gate structures and other features, as well as the dielectric materials therebetween, decrease to 25 nm and 20 nm dimensions and beyond, whereas the thickness of the dielectric layers remain substantially constant, with the result of increasing the aspect ratios of the features. Furthermore, reduced channel length often causes significant short channel effect with conventional planar MOSFET architecture. In order to enable fabrication of next generation devices and structures, three dimensional (3D) device structure is often utilized to improve performance of the transistors. In particular, fin field effect transistors (FinFET) are often utilized to enhance device performance. FinFET devices typically include semiconductor fins with high aspect ratios in which the channel and source/drain regions for the transistor are formed thereover. A gate electrode is then formed over and along side of a portion of the fin devices utilizing the advantage of the increased surface area of the channel and source/drain regions to produce faster, more reliable and better-controlled semiconductor transistor devices. Further advantages of FinFETs include reducing the short channel effect and providing higher current flow. Device structures with hGAA configurations often provide superior electrostatic control by surrounding gate to suppress short channel effect and associated leakage current.

In some applications, horizontal gate-all-around (hGAA) structures are utilized for next generation semiconductor device applications. The hGAA device structure includes several lattice matched channels (e.g., nanowires) suspended in a stacked configuration and connected by source/drain regions.

In hGAA structures, different materials are often utilized to form the channel structures (e.g., nanowires), which may undesirably increase the manufacturing difficulty in integrating all these materials in the nanowire structures without deteriorating the device performance. For example, one of the challenges associated with hGAA structures include the existence of large parasitic capacitance between the metal gate and source/drain. Improper management of such parasitic capacitance may result in much degraded device performance.

Thus, there is a need for improved methods for forming channel structures with proper materials for hGAA device structures on a substrate with good profile and dimension control.

### SUMMARY

The present disclosure provides methods for forming nanowire spacers for nanowire structures with desired materials in horizontal gate-all-around (hGAA) structures for semiconductor chips. In one example, a method of forming nanowire spaces for nanowire structures on a substrate includes performing a lateral etching process on a substrate having a multi-material layer disposed thereon, wherein the multi-material layer including repeating pairs of a first layer and a second layer, the first and second layers each having a first sidewall and a second sidewall respectively exposed in the multi-material layer, wherein the lateral etching process predominately etches the second layer through the second layer forming a recess in the second layer, filling the recess with a dielectric material, and removing the dielectric layer extending out of the recess.

### DETAILED DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

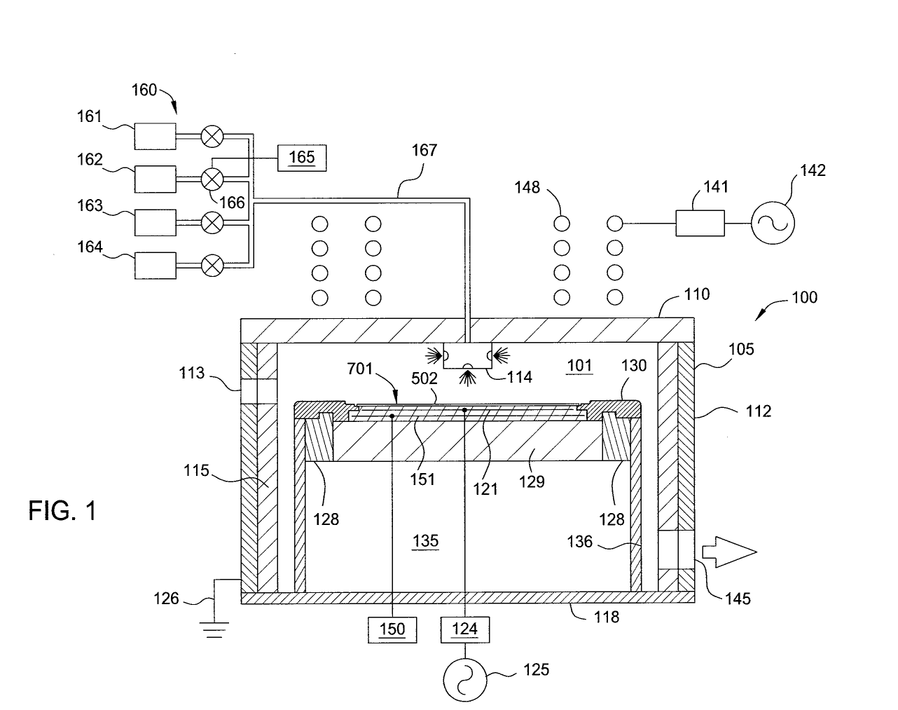

FIG. 1 depicts a plasma processing chamber which may be utilized to perform an etching process on a substrate;

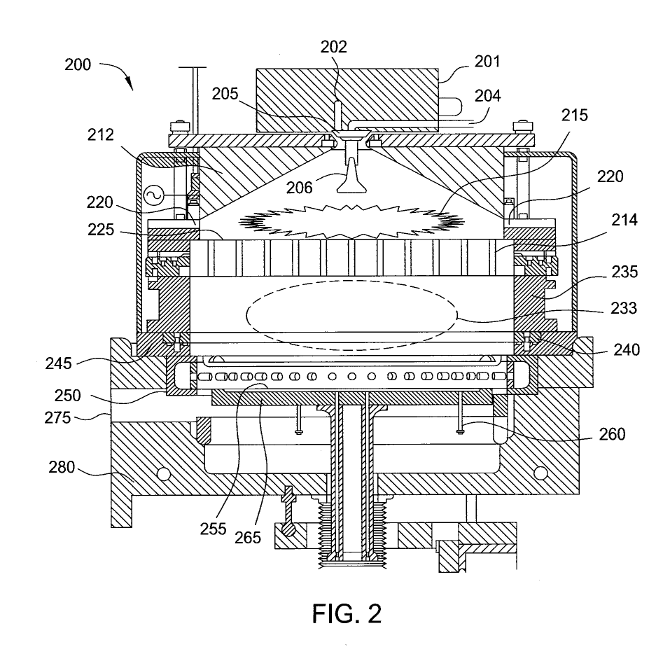

FIG. 2 depicts a plasma processing chamber which may be utilized to perform a deposition process on a substrate;

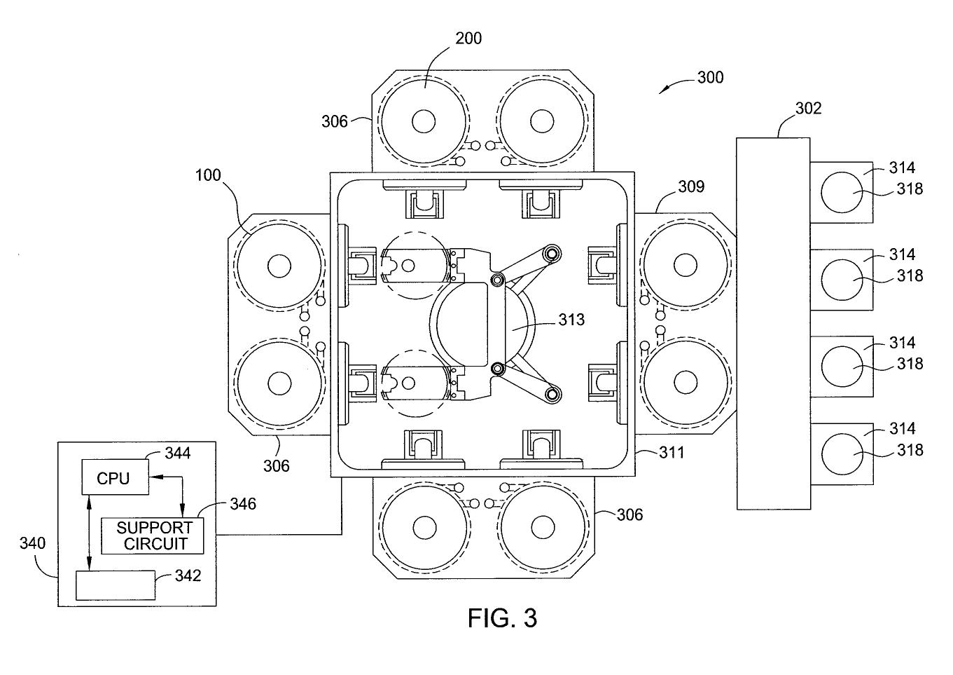

FIG. 3 depicts a processing system that may include plasma processing chambers of FIGS. 1 and 2 to be incorporated therein;

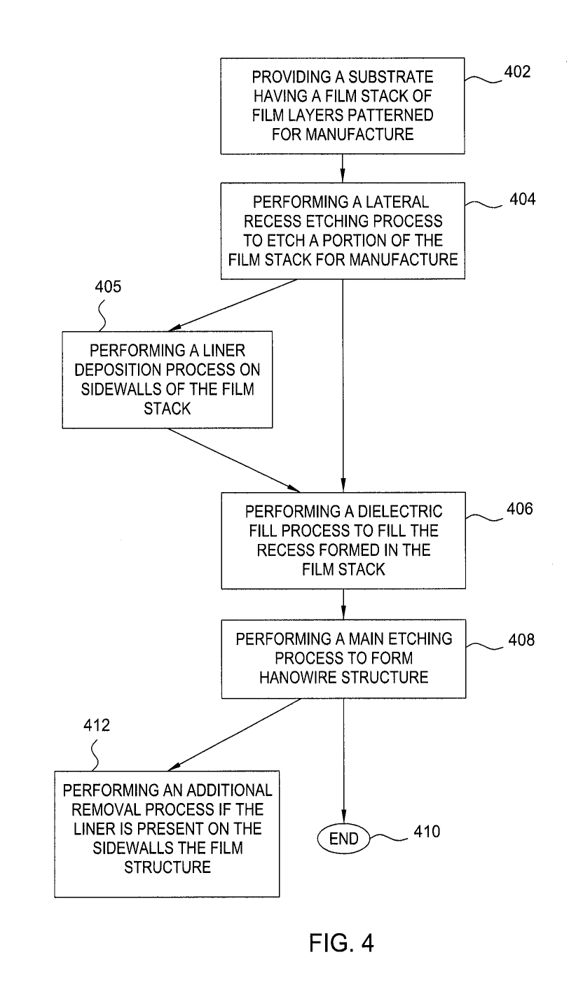

FIG. 4 depicts a flow diagram of a method for manufacturing nanowire structures formed on a substrate;

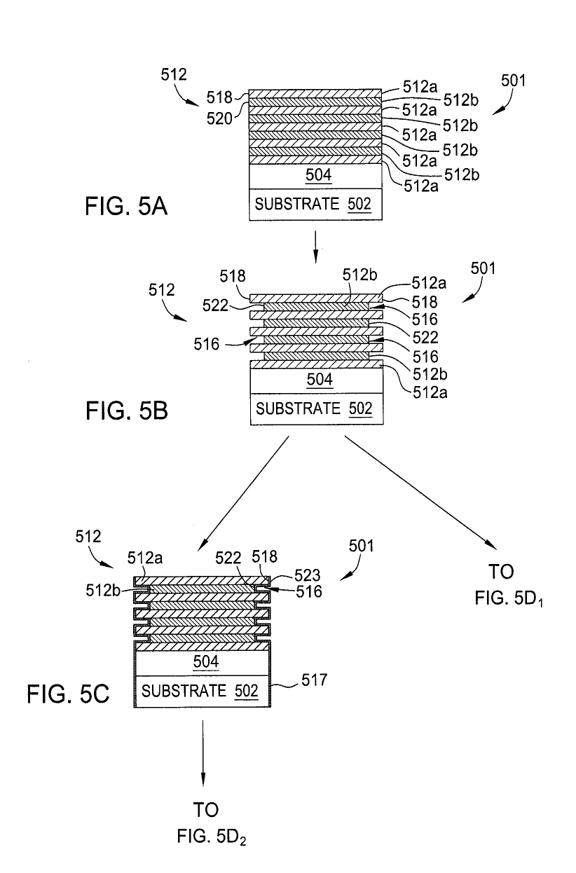

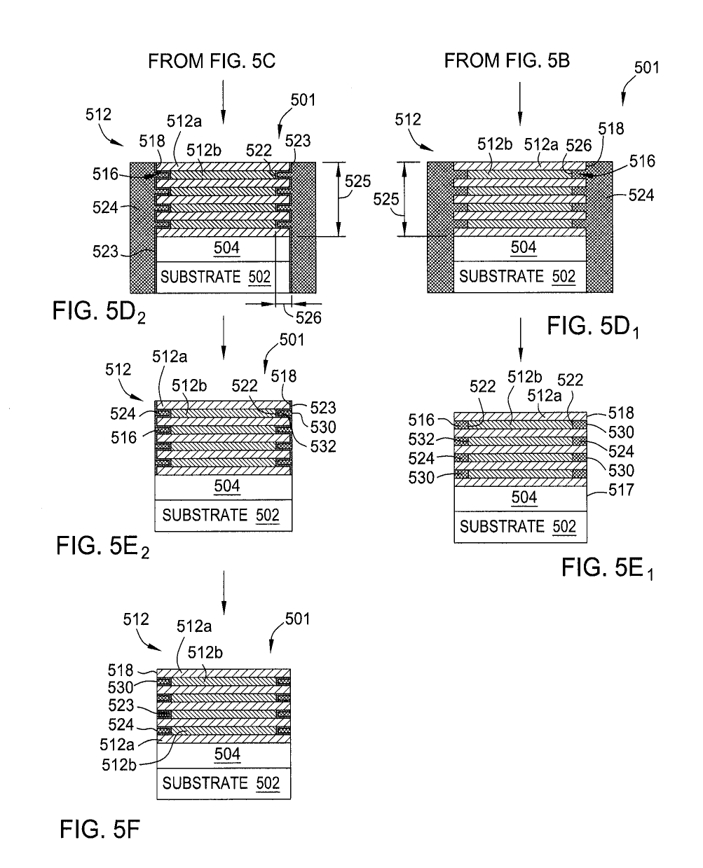

FIGS. 5A-5F depict cross sectional views of one example of a sequence for forming a nanowire structure with desired materials during the manufacturing process of FIG. 4; and

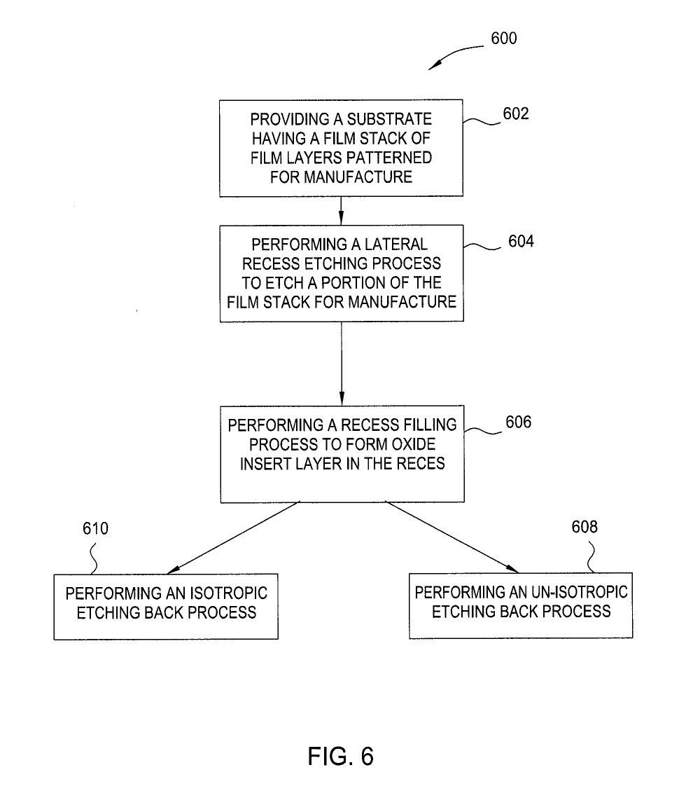

FIG. 6 depicts a flow diagram of another method for manufacturing nanowire structures formed on a substrate;

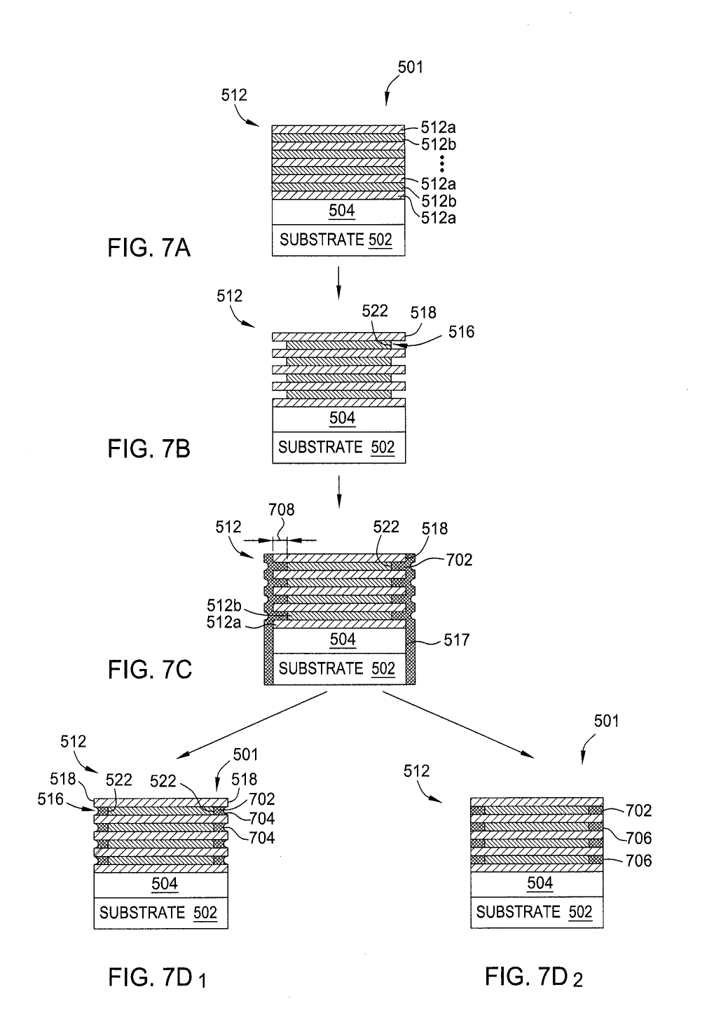

FIGS. 7A-7D₂ depict cross sectional views of one example of a sequence for forming a nanowire structure with desired materials during the manufacturing process of FIG. 6;

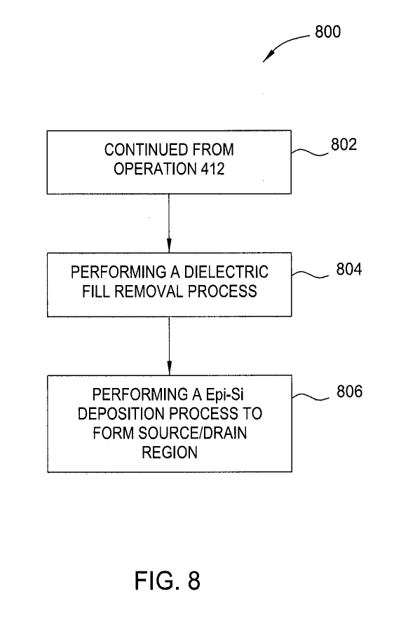

FIG. 8 depicts a flow diagram of yet another method for manufacturing nanowire structures formed on a substrate;

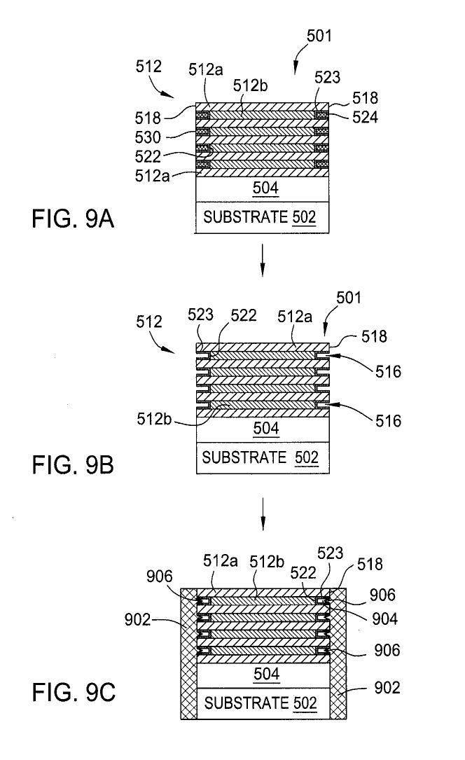

FIGS. 9A-9C depict cross sectional views of one example of a sequence for forming a nanowire structure with desired materials during the manufacturing process of FIG. 8;

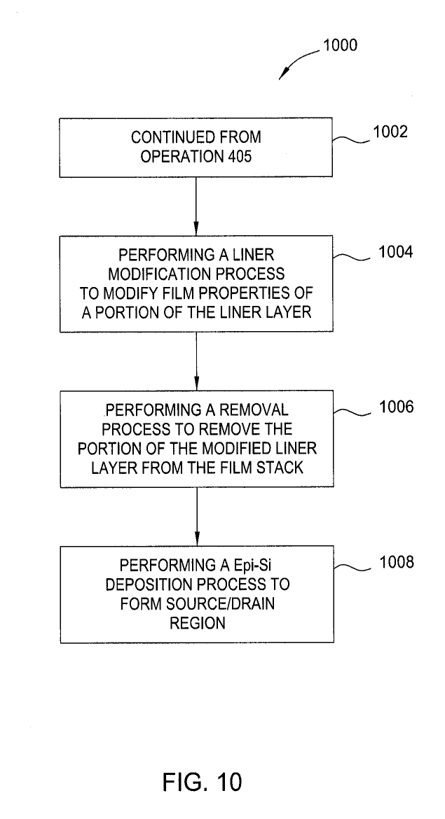

FIG. 10 depicts a flow diagram of yet another method for manufacturing nanowire structures formed on a substrate;

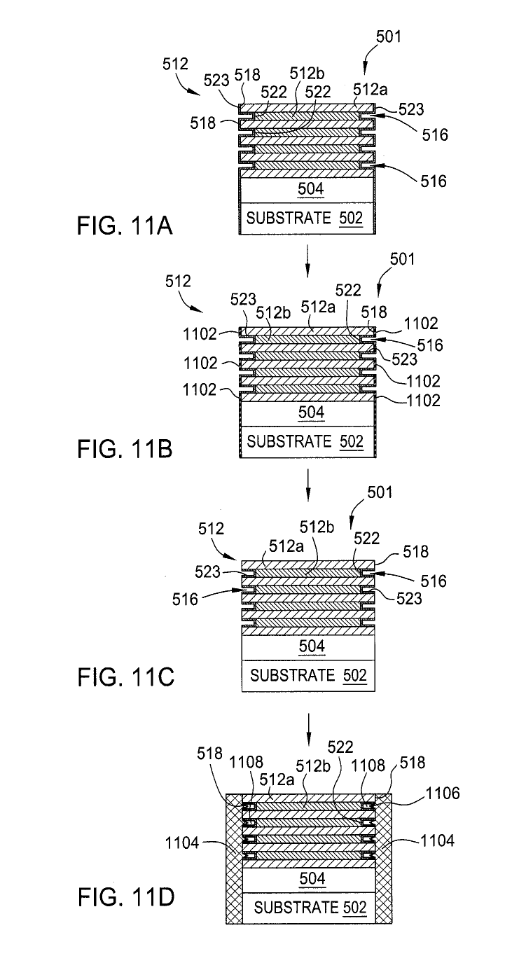

FIGS. 11A-11D depict cross sectional views of one example of a sequence for forming a nanowire structure with desired materials during the manufacturing process of FIG. 10; and

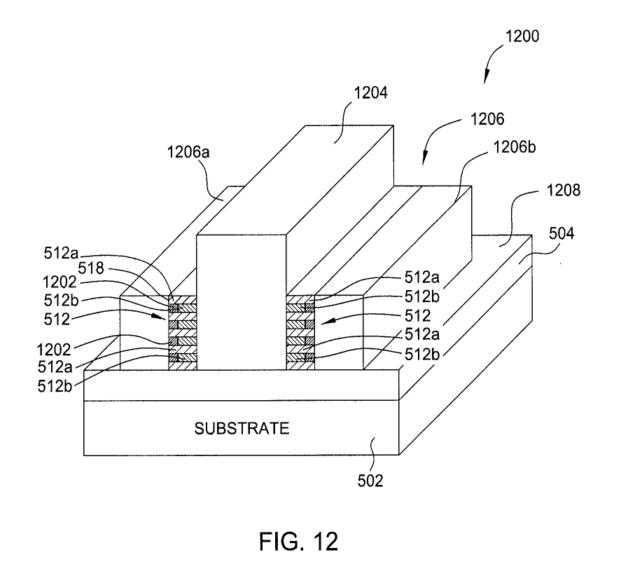

FIG. 12 depict a schematic view of an example of a horizontal gate-all-around (hGAA) structure.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Methods for manufacturing nanowire spacers in nanowire structures with controlled parasitic capacitance for a horizontal gate-all-around (hGAA) semiconductor device structure are provided. In one example, a superlattice structure comprising different materials (e.g., a first material and a second material) arranged in an alternatingly stacked formation may be formed on a substrate to be later utilized as nanowires (e.g., channel structures) for horizontal gate-all-around (hGAA) semiconductor device structures. A sequence of deposition and etching processes may be performed to form nanowire spacers in nanowire structures with low parasitic capacitance. The nanowire spacers formed on sidewalls of the first material in the superlattice structure are selected from a group of materials with reduced parasitic capacitance. A liner structure may be formed between the first material and the nanowire spacers as needed. Suitable materials for the nanowire spacers include low-k materials, dielectric materials, or even air gap.

FIG. 1 is a simplified cutaway view for an exemplary etching processing chamber 100 for etching a metal layer. The exemplary etching processing chamber 100 is suitable for removing one or more film layers from the substrate 502. One example of the process chamber that may be adapted to benefit from the invention is an AdvantEdge Mesa Etch processing chamber, available from Applied Materials, Inc., located in Santa Clara, Calif. It is contemplated that other process chambers, including those from other manufactures, may be adapted to practice embodiments of the invention.

The etch processing chamber 100 includes a chamber body 105 having a chamber volume 101 defined therein. The chamber body 105 has sidewalls 112 and a bottom 118 which are coupled to ground 126. The sidewalls 112 have a liner 115 to protect the sidewalls 112 and extend the time between maintenance cycles of the etching processing chamber 100. The dimensions of the chamber body 105 and related components of the etching processing chamber 100 are not limited and generally are proportionally larger than the size of the substrate 502 to be processed therein. Examples of substrate sizes include 200 mm diameter, 250 mm diameter, 300 mm diameter and 450 mm diameter, among others.

The chamber body 105 supports a chamber lid assembly 110 to enclose the chamber volume 101. The chamber body 105 may be fabricated from aluminum or other suitable materials. A substrate access port 113 is formed through the sidewall 112 of the chamber body 105, facilitating the transfer of the substrate 502 into and out of the etching processing chamber 100. The access port 113 may be coupled to a transfer chamber and/or other chambers of a substrate processing system (not shown).

A pumping port 145 is formed through the sidewall 112 of the chamber body 305 and connected to the chamber volume 101. A pumping device (not shown) is coupled through the pumping port 145 to the chamber volume 101 to evacuate and control the pressure therein. The pumping device may include one or more pumps and throttle valves.

A gas panel 160 is coupled by a gas line 167 to the chamber body 105 to supply process gases into the chamber volume 101. The gas panel 160 may include one or more process gas sources 161, 162, 163, 164 and may additionally include inert gases, non-reactive gases, and reactive gases, if desired. Examples of process gases that may be provided by the gas panel 160 include, but are not limited to, hydrocarbon containing gas including methane (CH₄), sulfur hexafluoride (SF₆), carbon tetrafluoride (CF₄), hydrogen bromide (HBr), hydrocarbon containing gas, argon gas (Ar), chlorine (Cl₂), nitrogen (N2), and oxygen gas (O₂). Additionally, process gasses may include chlorine, fluorine, oxygen and hydrogen containing gases such as BCl₃, O₄F₈, C₄F₆, CHF₃, CH₂F₂, CH₃F, NF₃, CO₂, SO₂, CO, and H₂ among others.

Valves 166 control the flow of the process gases from the sources 161, 162, 163, 164 from the gas panel 160 and are managed by a controller 165. The flow of the gases supplied to the chamber body 105 from the gas panel 160 may include combinations of the gases.

The lid assembly 110 may include a nozzle 114. The nozzle 114 has one or more ports for introducing the process gases from the sources 161, 162, 164, 163 of the gas panel 160 into the chamber volume 101. After the process gases are introduced into the etching processing chamber 100, the gases are energized to form plasma. An antenna 148, such as one or more inductor coils, may be provided adjacent to the etching processing chamber 100. An antenna power supply 142 may power the antenna 148 through a match circuit 141 to inductively couple energy, such as RF energy, to the process gas to maintain a plasma formed from the process gas in the chamber volume 101 of the etch processing chamber 100. Alternatively, or in addition to the antenna power supply 142, process electrodes below the substrate 502 and/or above the substrate 502 may be used to capacitively couple RF power to the process gases to maintain the plasma within the chamber volume 101. The operation of the antenna power supply 142 may be controlled by a controller, such as controller 165, that also controls the operation of other components in the etch processing chamber 100.

A substrate support pedestal 135 is disposed in the chamber volume 101 to support the substrate 502 during processing. The substrate support pedestal 135 may include an electro-static chuck 122 for holding the substrate 502 during processing. The electro-static chuck (ESC) 122 uses the electro-static attraction to hold the substrate 502 to the substrate support pedestal 135. The ESC 122 is powered by an RF power supply 125 integrated with a match circuit 124. The ESC 122 comprises an electrode 121 embedded within a dielectric body. The RF power supply 125 may provide a RF chucking voltage of about 200 volts to about 2000 volts to the electrode 121. The RF power supply 125 may also include a system controller for controlling the operation of the electrode 121 by directing a DC current to the electrode 121 for chucking and de-chucking the substrate 502.

The ESC 122 may also include an electrode 151 deposed therein. The electrode 151 is coupled to a power source 150 and provides a bias which attracts plasma ions, formed by the process gases in the chamber volume 101, to the ESC 122 and substrate 502 positioned thereon. The power source 150 may cycle on and off, or pulse, during processing of the substrate 502. The ESC 122 has an isolator 128 for the purpose of making the sidewall of the ESC 122 less attractive to the plasma to prolong the maintenance life cycle of the ESC 122. Additionally, the substrate support pedestal 135 may have a cathode liner 136 to protect the sidewalls of the substrate support pedestal 135 from the plasma gases and to extend the time between maintenance of the plasma etch processing chamber 100.

The ESC 122 may include heaters disposed therein and connected to a power source (not shown), for heating the substrate, while a cooling base 129 supporting the ESC 122 may include conduits for circulating a heat transfer fluid to maintain a temperature of the ESC 122 and the substrate 502 disposed thereon. The ESC 122 is configured to perform in the temperature range required by the thermal budget of the device being fabricated on the substrate 502. For example, the ESC 122 may be configured to maintain the substrate 502 at a temperature of about minus about 25 degrees Celsius to about 500 degrees Celsius for certain embodiments.

The cooling base 129 is provided to assist in controlling the temperature of the substrate 502. To mitigate process drift and time, the temperature of the substrate 502 may be maintained substantially constant by the cooling base 129 throughout the time the substrate 502 is in the etch chamber. In one embodiment, the temperature of the substrate 502 is maintained throughout subsequent etch processes at about 70 to 90 degrees Celsius.

A cover ring 130 is disposed on the ESC 122 and along the periphery of the substrate support pedestal 135. The cover ring 130 is configured to confine etching gases to a desired portion of the exposed top surface of the substrate 502, while shielding the top surface of the substrate support pedestal 135 from the plasma environment inside the etch processing chamber 100. Lift pins (not shown) are selectively moved through the substrate support pedestal 135 to lift the substrate 502 above the substrate support pedestal 135 to facilitate access to the substrate 502 by a transfer robot (not shown) or other suitable transfer mechanism.

The controller 165 may be utilized to control the process sequence, regulating the gas flows from the gas panel 160 into the etch processing chamber 100 and other process parameters. Software routines, when executed by the CPU, transform the CPU into a specific purpose computer (controller) that controls the etch processing chamber 100 such that the processes are performed in accordance with the present invention. The software routines may also be stored and/or executed by a second controller (not shown) that is collocated with the etch processing chamber 100.

The substrate 502 has various film layers disposed thereon which may include at least one metal layer. The various film layers may require etch recipes which are unique for the different compositions of the other film layers in the substrate 502. Multilevel interconnects that lie at the heart of the VLSI and ULSI technology may require the fabrication of high aspect ratio features, such as vias and other interconnects. Constructing the multilevel interconnects may require one or more etch recipes to form patterns in the various film layers. These recipes may be performed in a single etch processing chamber or across several etch processing chambers. Each etch processing chamber may be configured to etch with one or more of the etch recipes. In one embodiment, etch processing chamber 100 is configured to at least etch a metal layer to form an interconnection structure. For processing parameters provided herein, the etch processing chamber 100 is configured to process a 300 diameter substrate, i.e., a substrate having a plan area of about 0.0707 m². The process parameters, such as flow and power, may generally be scaled proportionally with the change in the chamber volume or substrate plan area.

FIG. 2 is a cross-sectional view of one embodiment of a flowable chemical vapor deposition chamber 200 with partitioned plasma generation regions. The flowable chemical vapor deposition chamber 200 may be utilized to deposit a liner layer, such as a SiOC containing layer, onto a substrate. During film deposition (silicon oxide, silicon nitride, silicon oxynitride, silicon carbide, or silicon oxycarbide depositions), a process gas may be flowed into a first plasma region 215 through a gas inlet assembly 205. The process gas may be excited prior to entering the first plasma region 215 within a remote plasma system (RPS) 201. The deposition chamber 200 includes a lid 212 and showerhead 225. The lid 212 is depicted with an applied AC voltage source and the showerhead 225 is grounded, consistent with plasma generation in the first plasma region 215. An insulating ring 220 is positioned between the lid 212 and the showerhead 225 enabling a capacitively coupled plasma (CCP) to be formed in the first plasma region 215. The lid 212 and showerhead 225 are shown with an insulating ring 220 in between, which allows an AC potential to be applied to the lid 212 relative to the showerhead 225.

The lid 212 may be a dual-source lid for use with a processing chamber. Two distinct gas supply channels are visible within the gas inlet assembly 205. A first channel 202 carries a gas that passes through the remote plasma system (RPS) 201, while a second channel 204 bypasses the RPS 201. The first channel 202 may be used for the process gas and the second channel 204 may be used for a treatment gas. The gases that flow into the first plasma region 215 may be dispersed by a baffle 206.

A fluid, such as a precursor, may be flowed into a second plasma region 233 of the deposition chamber 200 through the showerhead 225. Excited species derived from the precursor in the first plasma region 215 travel through apertures 214 in the showerhead 225 and react with the precursor flowing into the second plasma region 233 from the showerhead 225. Little or no plasma is present in the second plasma region 233. Excited derivatives of the precursor combine in the second plasma region 233 to form a flowable dielectric material on the substrate. As the dielectric material grows, more recently added material possesses a higher mobility than underlying material. Mobility decreases as organic content is reduced by evaporation. Gaps may be filled by the flowable dielectric material using this technique without leaving traditional densities of organic content within the dielectric material after deposition is completed. A curing step may still be used to further reduce or remove the organic content from a deposited film.

Exciting the precursor in the first plasma region 215 alone or in combination with the remote plasma system (RPS) 201 provides several benefits. The concentration of the excited species derived from the precursor may be increased within the second plasma region 233 due to the plasma in the first plasma region 215. This increase may result from the location of the plasma in the first plasma region 215. The second plasma region 233 is located closer to the first plasma region 215 than the remote plasma system (RPS) 201, leaving less time for the excited species to leave excited states through collisions with other gas molecules, walls of the chamber and surfaces of the showerhead.

The uniformity of the concentration of the excited species derived from the precursor may also be increased within the second plasma region 233. This may result from the shape of the first plasma region 215, which is more similar to the shape of the second plasma region 233. Excited species created in the remote plasma system (RPS) 201 travel greater distances in order to pass through apertures 214 near the edges of the showerhead 225 relative to species that pass through apertures 214 near the center of the showerhead 225. The greater distance results in a reduced excitation of the excited species and, for example, may result in a slower growth rate near the edge of a substrate. Exciting the precursor in the first plasma region 215 mitigates this variation.

In addition to the precursors, there may be other gases introduced at varied times for varied purposes. A treatment gas may be introduced to remove unwanted species from the chamber walls, the substrate, the deposited film and/or the film during deposition. The treatment gas may comprise at least one of the gases from the group comprising of H₂, an H₂/N₂ mixture, NH₃, NH₄OH, O₃, O₂, H₂O₂ and water vapor. A treatment gas may be excited in a plasma and then used to reduce or remove a residual organic content from the deposited film. In other embodiments, the treatment gas may be used without a plasma. When the treatment gas includes water vapor, the delivery may be achieved using a mass flow meter (MFM) and injection valve or by other suitable water vapor generators.

In the embodiment, the dielectric layer can be deposited by introducing dielectric material precursors, e.g., a silicon containing precursor, and reacting processing precursors in the second plasma region 233. Examples of dielectric material precursors are silicon-containing precursors including silane, disilane, methylsilane, dimethylsilane, trimethylsilane, tetramethylsilane, tetraethoxysilane (TEOS), triethoxysilane (TES), octamethylcyclotetrasiloxane (OMCTS), tetramethyl-disiloxane (TMDSO), tetramethylcyclotetrasiloxane (TMCTS), tetramethyl-diethoxyl-disiloxane (TMDDSO), dimethyl-dimethoxyl-silane (DMDMS) or combinations thereof. Additional precursors for the deposition of silicon nitride include SixNyHz-containing precursors, such as sillyl-amine and its derivatives including trisillylamine (TSA) and disillylamine (DSA), SixNyHzOzz-containing precursors, SixNyHzClzz-containing precursors, or combinations thereof.

Processing precursors include hydrogen-containing compounds, oxygen-containing compounds, nitrogen-containing compounds, or combinations thereof. Examples of suitable processing precursors include one or more of compounds selected from the group comprising of H₂, a H₂/N₂ mixture, NH₃, NH₄OH, O₃, O₂, H₂O₂, N₂, NxHy compounds including N₂H₄ vapor, NO, N₂O, NO₂, water vapor, or combinations thereof. The processing precursors may be plasma exited, such as in the RPS unit, to include N* and/or H* and/or O*-containing radicals or plasma, for example, NH₃, NH₂*, NH*, N*, H*, O*, N*O*, or combinations thereof. The process precursors may alternatively, include one or more of the precursors described herein.

The processing precursors may be plasma excited in the first plasma region 215 to produce process gas plasma and radicals including N* and/or H* and/or O* containing radicals or plasma, for example, NH₃, NH₂*, NH*, N*, H*, O*, N*O*, or combinations thereof. Alternatively, the processing precursors may already be in a plasma state after passing through a remote plasma system prior to introduction to the first plasma region 215.

The excited processing precursor is then delivered to the second plasma region 233 for reaction with the precursors through apertures 214. Once in the processing volume, the processing precursor may mix and react to deposit the dielectric materials.

In one embodiment, the Plowable CVD process performed in the deposition chamber 200 may deposit the dielectric materials as a polysilazanes based silicon containing film (PSZ-like film), which may be reflowable and fillable within trenches, features, vias, or other apertures defined in a substrate where the polysilazanes based silicon containing film is deposited.

In addition to the dielectric material precursors and processing precursors, there may be other gases introduced at varied times for varied purposes. A treatment gas may be introduced to remove unwanted species from the chamber walls, the substrate, the deposited film and/or the film during deposition, such as hydrogen, carbon, and fluorine. A processing precursor and/or treatment gas may comprise at least one of the gases from the group comprising H₂, a H₂/N₂ mixture, NH₃, NH₄OH, O₃, O₂, H₂O₂, N₂, N₂H₄ vapor, NO, N₂O, NO₂, water vapor, or combinations thereof. A treatment gas may be excited in a plasma and then used to reduce or remove a residual organic content from the deposited film. In other disclosed embodiments the treatment gas may be used without a plasma. When the treatment gas includes water vapor, the delivery may be achieved using a mass flow meter (MFM) and injection valve or by commercially available water vapor generators. The treatment gas may be introduced from into the first processing region, either through the RPS unit or bypassing the RPS unit, and may further be excited in the first plasma region.

Silicon nitrides materials include silicon nitride, SixNy, hydrogen-containing silicon nitrides, SixNyHz, silicon oxynitrides, including hydrogen-containing silicon oxynitrides, SixNyHzOzz, and halogen-containing silicon nitrides, including chlorinated silicon nitrides, SixNyHzClzz. The deposited dielectric material may then be converted to a silicon oxide like material.

FIG. 3 depicts a plan view of a semiconductor processing system 300 that the methods described herein may be practiced. One processing system that may be adapted to benefit from the invention is a 300 mm or 450 mm Producer™ processing system, commercially available from Applied Materials, Inc., of Santa Clara, Calif. The processing system 300 generally includes a front platform 302 where substrate cassettes 318 included in FOUPs 314 are supported and substrates are loaded into and unloaded from a loadlock chamber 309, a transfer chamber 311 housing a substrate handler 313 and a series of tandem processing chambers 306 mounted on the transfer chamber 311.

Each of the tandem processing chambers 306 includes two process regions for processing the substrates. The two process regions share a common supply of gases, common pressure control, and common process gas exhaust/pumping system. Modular design of the system enables rapid conversion from any one configuration to any other. The arrangement and combination of chambers may be altered for purposes of performing specific process steps. Any of the tandem processing chambers 306 can include a lid according to aspects of the invention as described below that includes one or more chamber configurations described above with referenced to the processing chamber 100, 200 depicted in FIG. 1 and/or FIG. 2. It is noted that the processing system 300 may be configured to perform a deposition process, etching process, curing processes, or heating/annealing process as needed. In one embodiment, the processing chambers 100, 200, shown as a single chamber designed in FIGS. 1 and 2, may be incorporated into the semiconductor processing system 300.

In one implementation, the processing system 300 can be adapted with one or more of the tandem processing chambers having supporting chamber hardware known to accommodate various other known processes such as chemical vapor deposition (CVD), physical vapor deposition (PVD), etching, curing, or heating/annealing and the like. For example, the processing system 300 can be configured with one of the processing chambers 100 in FIG. 1 as a plasma deposition chamber for deposition, such as a dielectric film, or one of the processing chambers 200 depicted in FIG. 2 as a plasma etching chamber for etching material layers formed on the substrates. Such a configuration can maximize research and development fabrication utilization and, if desired, eliminate exposure of films as etched to atmosphere.

A controller 340, including a central processing unit (CPU) 344, a memory 342, and support circuits 346, is coupled to the various components of the semiconductor processing system 300 to facilitate control of the processes of the present invention. The memory 342 can be any computer-readable medium, such as random access memory (RAM), read only memory (ROM), floppy disk, hard disk, or any other form of digital storage, local or remote to the semiconductor processing system 300 or CPU 344. The support circuits 346 are coupled to the CPU 344 for supporting the CPU in a conventional manner. These circuits include cache, power supplies, clock circuits, input/output circuitry and subsystems, and the like. A software routine or a series of program instructions stored in the memory 342, when executed by the CPU 344, executes the tandem processing chambers 306.

FIG. 4 is a flow diagram of one example of a method 400 for manufacturing nanowire spacers in nanowire structures (e.g., channel structures) with composite materials for horizontal gate-all-around (hGAA) semiconductor device structures. FIGS. 5A-5F are cross-sectional views of a portion of a composite substrate corresponding to various stages of the method 400. The method 400 may be utilized to form the nanowire spacers in nanowire structures for horizontal gate-all-around (hGAA) semiconductor devices on a substrate. Alternatively, the method 400 may be beneficially utilized to manufacture other types of structures.

The method 400 begins at operation 402 by providing a substrate, such as the substrate 502 depicted in FIG. 1, having a film stack 501 formed thereon, as shown in FIG. 5A. The substrate 502 may be a material such as crystalline silicon (e.g., Si<100> or Si<111>), silicon oxide, strained silicon, silicon germanium, germanium, doped or undoped polysilicon, doped or undoped silicon wafers and patterned or non-patterned wafers silicon on insulator (SOI), carbon doped silicon oxides, silicon nitride, doped silicon, germanium, gallium arsenide, glass, or sapphire. The substrate 502 may have various dimensions, such as 200 mm, 300 mm, 450 mm or other diameter, as well as, being a rectangular or square panel. Unless otherwise noted, examples described herein are conducted on substrates with a 200 mm diameter, a 300 mm diameter, or a 450 mm diameter substrate.

The film stack 501 includes a multi-material layer 512 disposed on an optional material layer 504. In the embodiments wherein the optional material layer 504 is not present, the film stack 501 may be directly formed on the substrate 502 as needed. In one example, the optional material layer 504 is an insulating material. Suitable examples of the insulating material may include silicon oxide material, silicon nitride material, silicon oxynitride material, or any suitable insulating materials. Alternatively, the optional material layer 504 may be any suitable materials including conductive material or non-conductive material as needed. The multi-material layer 512 includes at least one pair of layers, each pair comprising a first layer 512a and a second layer 512b. Although the example depicted in FIG. 5A shows four pairs, each pair including the first layer 512a and the second layer 512b (alternating pairs, each pair comprising the first layer 512a and the second layer 512b) with an additional first layer 512a on the top, it is noted that number of pairs may be varied based on different process needs with extra or without extra first layer 512a or second layer 512b be as needed. In one implementation, the thickness of each single first layer 512a may be at between about 20 Å and about 200 Å, such as about 50 Å, and the thickness of the each single second layer 512b may be at between about 20 Å and about 200 Å, such as about 50 Å. The multi-material layer 512 may have a total thickness between about 10 Å and about 5000 Å, such as between about 40 Å and about 4000 Å.

The first layer 512a may be a crystalline silicon layer, such as a single crystalline, polycrystalline, or monocrystalline silicon layer, formed by an epitaxial deposition process. Alternatively, the first layer 512a a may be a doped silicon layer, including a p-type doped silicon layer or a n-type doped layer. Suitable p-type dopant includes B dopants, Al dopants, Ga dopants, In dopants, or the like. Suitable n-type dopant includes N dopants, P dopants, As dopants, Sb dopants, or the like. In yet another example, the first layer 512a may be a group III-V material, such as a GaAs layer.

The second layer 512b may be a Ge containing layer, such as a SiGe layer, Ge layer, or other suitable layer. Alternatively, the second layer 512b may be a doped silicon layer, including a p-type doped silicon layer or a n-type doped layer. In yet another example, the second layer 512b may be a group III-V material, such as a GaAs layer. In still another example, the first layer 512a may be a silicon layer and the second layer 512b is a metal material having a high-k material coating on outer surfaces of the metal material. Suitable examples of the high-k material includes hafnium dioxide (HfO2), zirconium dioxide (ZrO2), hafnium silicate oxide (HfSiO4), hafnium aluminum oxide (HfAlO), zirconium silicate oxide (ZrSiO4), tantalum dioxide (TaO2), aluminum oxide, aluminum doped hafnium dioxide, bismuth strontium titanium (BST), or platinum zirconium titanium (PZT), among others. In one particular implementation the coating layer is a hafnium dioxide (HfO2) layer.

In the particular example depicted in FIG. 5A, the first layer 512a is a crystalline silicon layer, such as a single crystalline, polycrystalline, or monocrystalline silicon layer. The second layer 512b is a SiGe layer.

In some examples, a hardmask layer (not shown in FIG. 5A) and/or a patterned photoresist layer may be disposed on the multi-material layer 512 for patterning the multi-material layer 512. In the example shown in FIG. 5A, the multi-material layer 512 has been patterned in the previous patterning processes, which may later have source/drain anchors formed therein, in the multi-material layer 512.

In the implementation wherein the substrate 502 is a crystalline silicon layer and the optional material layer 504 is a silicon oxide layer, the first layer 512a may be intrinsic epi-silicon layer and the second layer 512b is a SiGe layer. In another implementation, the first layer 512a may be a doped silicon containing layer and the second layer 512b may be an intrinsic epi-silicon layer. The doped silicon containing layer may be a p-type dopant or a n-type dopant, or a SiGe layer as needed. In yet another implementation wherein the substrate 502 is a Ge or GaAs substrate, the first layer 512a may be a GeSi layer and the second layer 512b may be an intrinsic epi-Ge layer or vice versa. In still another implementation wherein the substrate 502 is a GaAs layer with dominantly a crystalline plane at <100>, the first layer 512a may be an intrinsic Ge layer and the second layer 512b is a GaAs layer or vice versa. It is noted that the selection of the substrate materials along with the first layer 512a and the second layer 512b in the multi-material layer 512 may be in different combinations utilizing the materials listed above.

At operation 404, a lateral etching process is performed to laterally remove a portion of the second layer 512b from its sidewalls 520 from the film stack 501, as shown in FIG. 5B. The lateral etching process is performed to selectively remove (partially or entirely) one type of material from the substrate 502. For example, the second layer 512b may be partially removed as depicted in FIG. 5B, forming a recess 516 at each sidewall 520 of the second layer 512b, forming an exposed sidewall 522 of the second layer 512b. Alternatively, during the selective etching process, the first layer 512a may be partially removed as needed (not shown) from its sidewall 518, rather than the second layer 512b depicted in FIG. 5B.

Based on different process requirements, different etching precursors are selected to selectively and specifically etch either the first layer 512a or the second layer 512b from the substrate 502 to form the recess 516. As the first and the second layers 512a, 512b on the substrate 502 has substantially the same dimensions and have sidewalls 518, 520 (shown FIG. 5A) exposed for etching, the etching precursors selected to have high selectivity between the first and the second layers 512a, 512b, and thus are be able to target and laterally etch only either the first layer 512a or the second layer 512b (the example shown in FIG. 5B) without attacking or damaging the other (i.e., non-target) layer. After a desired width of the targeted material is removed from the substrate 502, forming a recess for manufacturing nanowire spacers, which will be described in detail below, the lateral etching process at operation 404 may then be terminated.

In the example depicted in FIG. 5B, the etching precursors are selected particularly to etch the second layer 512b without attacking or damaging the first layer 512a. In the example depicted in FIG. 5B, the etching precursors are selected to particularly etch the second layer 512b without attacking or damaging the first layer 512a. In one example wherein the first layer 512a is an intrinsic epi-Si layer and the second layer 512b is a SiGe layer formed on the substrate 502, the etching precursor selected to etch the second layer 512b include at least a carbon fluorine containing gas supplied a plasma processing chamber, such as the processing chamber 100 depicted in FIG. 1. Suitable examples of the carbon fluorine containing gas may include CF₄, C₄F₆, C₄F₈, O₂F₂, CF₄, C₂F₆, C₅F₈, and the like. A reacting gas, such as O₂ or N2 may also be supplied with the carbon fluorine containing gas from the remote plasma source to promote the etching process. Further, a halogen containing gas may be supplied into the processing chamber 100 to generate a plasma by a RF source power or a bias RF power or both, to further assist the etching process. Suitable halogen containing gas may be supplied into the processing chamber include HCl, Cl₂, CCl₄, CHCl₃, CH₂Cl₂, CH₃Cl or the like. In one example, a CF₄ and O₂ gas mixture may be supplied from the remote plasma source while a Cl₂ gas may be supplied to the processing chamber to be dissociated by either a RF source power or a bias RF power or both in the chamber volume 101 defined in the processing chamber 100. The CF₄ and O₂ may have a flow rate ratio between about 100:1 and about 1:100.

During the lateral etching process, several process parameters may also be controlled while supplying the etching gas mixture to perform the etching process. The pressure of the processing chamber may be controlled at between about 0.5 milliTorr and about 3000 milliTorr, such as between about 2 milliTorr and about 500 milliTorr. A substrate temperature is maintained between about 15 degrees Celsius to about 300 degrees Celsius, such as greater than 50 degrees Celsius, for example between about 60 degrees Celsius and about 90 degrees Celsius. The RF source power may be supplied at the lateral etching gas mixture between about 50 Watts and about 3000 Watts and at a frequency between about 400 kHz and about 13.56 MHz. A RF bias power may also be supplied as needed. The RF bias power may be supplied at between about 0 Watts and about 1500 Watts.

While the process parameters may be controlled in a similar range, the chemical precursors selected to be supplied in the lateral etching mixture may be varied for different film layer etching request. For example, when the first layer 512a is an intrinsic epi-Si layer and the second layer 512b being etched is a material other than SiGe, such as a doped silicon material, the etching precursor selected to etch the second layer 512b, e.g., the doped silicon layer, be a halogen containing gas supplied into the processing chamber include Cl₂, HCl, or the like. The halogen containing gas, such as a Cl₂ gas, may be supplied to the processing chamber to be dissociated by either a RF source power or a bias RF power or both in the processing chamber 100.

At an optional operation 405, a liner layer 523 may be formed on sidewalls 518, 522 of the multi-material layer 512 as well as an outer surface 517 of the substrate 502 and the optional material layer 504, as shown in FIG. 5C. The liner layer 523 may provide an interface protection with a good interface adhesion and planarity for the materials formed thereon with good uniformity, conformity, adhesion and planarity. Thus, in the embodiment wherein the sidewalls 518, 522 of multi-material layer 512 is substantially planar with the desired straightness, the liner layer 523 in operation 405 may be eliminated and the operations thereafter may be directly performed on the sidewalls 518, 522 of multi-material layer 512, as later shown in FIGS. 5D₁ and 5E₁.

Although the structure shown in FIG. 5C only includes a single layer of the liner layer 523, it is noted that the liner layer 523 may be formed including more than one layer, such as composite layers, double layers, triple layers, or any suitable structures with any suitable number of layers.

In one example, the liner layer 523 may be selected from a material that may assist promote adhesion between the sidewalls 518, 522 of multi-material layer 512 and the materials later formed thereon with good adhesion at the interface. Furthermore, the liner layer 523 may have a sufficient thickness to fill in the nanoscale rough surface from the sidewalls 518, 522 of multi-material layer 512 so as to provide a substantially planar surface that allows the materials later formed thereon with a desired level of planarity, flatness and barrier capability to protect the multi-material layer 512 from attack during the following etching/patterning process. In one example, the liner layer 523 may have a thickness between about 0.5 nm and about 5 nm.

In one embodiment, the liner layer 523 is a silicon containing dielectric layer, such as a low-k material, silicon nitride containing layer, a silicon carbide containing layer, silicon oxygen containing layer, for example, SiN, SiON, SiC, SiCN, SiOC or silicon oxycarbonitride or silicon materials with dopants and the like. In one example, the liner layer 523 is a silicon nitride layer, silicon carbide or a silicon oxynitride (SiON) with a thickness between about 5 Å and about 50 Å, such as about 10 Å. The liner layer 523 may be formed by a CVD process, an ALD process or any suitable deposition techniques in a PVD, CVD, ALD, or other suitable plasma processing chambers.

At operation 406, after the optional liner layer 523 is formed on the sidewalls 518, 522 of multi-material layer 512, a dielectric fill deposition process may be performed to form a dielectric layer 524 filling on the substrate 502 in the multi-material layer 512, as shown in FIGS. 5D₁ and 5D₂. In the embodiment wherein the optional operation 405 is not performed and the liner layer 523 is not present on the substrate 502, the dielectric layer 524 may be formed on the substrate 502 in direct contact with the multi-material layer 512, as referenced in FIG. 5D₁.

The dielectric layer 524 formed on the substrate 502 may be filled in any open areas in the multi-material layer 512, including the recess 516 defined during the lateral etching process performed at operation 404. As the multi-material layer 512 may be previously patterned to form openings in the multi-material layer 512 (not shown in the embodiments depicted in FIGS. 5A-5F), the dielectric fill deposition process as performed may provide the dielectric layer 524 to fill in the open areas in the multi-material layer 512, which may be later utilized to form as nanowire spacer structures.

In one example, the dielectric fill deposition process may be a flowable CVD process, a cyclical layer deposition (CLD), an atomic layer deposition (ALD), a plasma enhanced chemical vapor deposition (PE CVD), a physical vapor deposition (PVD), a spin-on coating process, or any suitable deposition process to fill the dielectric layer 524 in the structure of the multi-material layer 512, including the recess 516 defined therein. The dielectric layer 524 may be filled in the multi-material layer 512 on the substrate 502 with a sufficient thickness to fill in the recess 516 as well as the open areas in the multi-material layer 512, including a depth 525 (e.g., the total thickness) of the multi-material layer 512.

In one example, the flowable CVD process is utilized to perform the dielectric fill deposition process in a flowable CVD processing chamber such as the processing chamber depicted in FIG. 2. The dielectric fill deposition process performed in the deposition chamber 200 is a flowable CVD process that forms the dielectric layer 524 as a polysilazanes based silicon containing film (PSZ-like film), which may be reflowable and fillable within trenches, features, vias, recess or other apertures defined in a substrate where the polysilazanes based silicon containing film is deposited.

As the dielectric layer 524 will later be utilized to form nanowire spacer structures, the material of the dielectric layer 524 as formed is selected to be a silicon containing material that may reduce parasitic capacitance between the fate and source/drain structure in the hGAA nanowire structure, such as a low-K material, a silicon containing material, such as silicon nitride, silicon oxide, silicon oxynitride, silicon carbide, silicon oxycarbide, silicon carbide nitride, doped silicon layer or other suitable materials, such as Black Diamond® material available from Applied Materials.

In one embodiment, the dielectric layer 524 is a low-k material (e.g., dielectric constant less than 4) or a silicon oxide/silicon nitride/silicon carbide containing material with a sufficient width 526 formed in the recess 516.

In operation 408, a main etching process is performed to etch the redundant dielectric layer 254 formed the substrate 502, as shown in FIGS. 5E₁ and 5E₂, leaving primarily the dielectric layer 524 in the recess 516 defined in the multi-material layer 512, which may be utilized to form as nanowire spacers after the device structure is completed, particularly for the hGAA device structure. The main etching process may be continuously performed to etch through the dielectric layer 524 overfilled from the multi-material layer 512 (e.g., from the sidewall 518 from the first layer 512a of the multi-material layer 512) so as to leave the dielectric layer 524 predominately filling in the recess 516, forming a recess outer sidewall 530 aligned with the sidewall 518 from the first layer 512a of the multi-material layer 512. Thus, the dielectric layer 524 formed in the recess 516 has a recess inner sidewall 532 in contact with the sidewall 522 of the second layer 512b of the multi-material layer 512 while having the recess outer sidewall 530 defining a vertical plane aligned with the plane defined by the sidewall 518 from the first layer 512a of the multi-material layer 512, as shown in FIG. 5E₁. In the example wherein the liner layer 523 is present (formed from the optional operation 405) on the substrate 502 lining on the sidewalls 518, 522 of the first and second layers 512a, 512b of the multi-material layer 512, as shown in FIG. 5E₂, the main etching process may be continuously performed until the liner layer 523 is exposed and the dielectric layer 524 is predominately formed in the recess 516 defined in the multi-material layer 512. In this example, an additional liner residual removal process may be performed at operation 412 to selectively remove the liner layer 523 from the substrate 502 (e.g., predominately remained on the sidewall 518 of the first layer 512a of the multi-material layer 512), as further shown in FIG. 5F. In contrast, when the liner layer 523 is not present on the substrate 502, after the nanowire spacer structure (e.g., the dielectric layer 524) is formed in the recess 516, the process is then considered completed in operation 410.

During the main etching process at operation 408, a main etching gas mixture including at least a halogen containing gas may be supplied into an etching processing chamber, such as the plasma processing chamber 100 of FIG. 1. Suitable examples of the halogen containing gas include CHF₃, CH₂F₂, CF₄, C₂F, C₄F₆, C₃F₈, HCl, C₄F₈, Cl₂, CCl₄, CHCl₃, CHF₃, C₂F₆, CH₂Cl₂, CH₃Cl, SF₆, NF₃, HBr, Br₂ and the like. While supplying the main etching gas mixture, an inert gas may also be supplied into the etching gas mixture to assist the profile control as needed. Examples of the inert gas supplied in the gas mixture include Ar, He, Ne, Kr, Xe or the like.

After the main etching gas mixture is supplied to the processing chamber mixture, a RF source power is supplied to form a plasma from the etching gas mixture therein. The RF source power may be supplied at the etching gas mixture between about 100 Watts and about 3000 Watts and at a frequency between about 400 kHz and about 13.56 MHz. A RF bias power may also be supplied as needed. The RF bias power may be supplied at between about 0 Watts and about 1500 Watts. In one implementation, the RF source power may be pulsed with a duty cycle between about 10 to about 95 percent at a RF frequency between about 500 Hz and about 10 MHz.

Several process parameters may also be controlled while supplying the etching gas mixture to perform the etching process. The pressure of the processing chamber may be controlled at between about 0.5 milliTorr and about 500 milliTorr, such as between about 2 milliTorr and about 100 milliTorr. A substrate temperature is maintained between about 15 degrees Celsius to about 300 degrees Celsius, such as greater than 50 degrees Celsius, for example between about 60 degrees Celsius and about 90 degrees Celsius etching process may be performed for between about 30 seconds and about 180 seconds.

As discussed above, after the main etching process at operation 408, the process may be considered completed, as shown in operation 410, when the liner layer 523 is not present on the substrate. In contrast, the process may be moved on to operation 412 when the liner layer 523 is present on the substrate to remove the residual liner layer 523 exposed on the substrate 502, lining on the sidewall 518 of the first layer 512a of the multi-material layer 512, as shown in FIG. 5F. The liner residual removal process may be any suitable cleaning process, including dry clean or wet clean process to remove the liner layer 523 exposed (e.g., the liner 523 formed on the sidewall 518 of the first layer 512a) from the substrate 502. It is noted that the liner layer 523 embedded and covered by the dielectric layer 524 formed in the recess 516 is remained on the substrate 502 after the liner residual removal process at operation 412. Such liner residual removal process may have a high selectivity for the liner layer 523 to the dielectric layer 524 as well as to the silicon materials, such as the intrinsic epi-Si layer or SiGe materials, in the multi-material layer 512 (for example, high selectivity for a silicon nitride layer to a silicon oxide layer and/or also to an intrinsic silicon layer or a doped silicon material) so as to successfully remove the redundant liner layer 523 and the dielectric layer 524 without adversely damaging the multi-material layer 512, including the first layer 512a and the second layer 512b.

In one example, the liner residual removal process may be performed by supplying a liner residual removal gas mixture including at least a hydrogen (H₂) and NF₃ gas. The hydrogen gas and the NF₃ gas supplied in the liner residual removal gas mixture may have a ratio (H₂ gas: NF₃ gas) between about 0.5:1 and about 15:1, such as between about 2:1 and about 9:1. Under such gas ratio control, the liner residual removal process may have a silicon oxide to silicon nitride selectivity (SiO₂:SiN) between about 0.7 and about 2.5. The process pressure may be controlled between about 0.1 Torr and about 10 Torr, such as about 1 Torr and 5 Torr. In some example, inert gas, such as He gas or Ar gas, may be also supplied in the liner residual removal gas mixture. In one example, the inert gas, such as He gas, may be supplied at between about 400 sccm and about 1200 sccm. A remote plasma power of between 15 Watts and about 45 Watts may be utilized to perform the liner residual removal process.

It is believed, but not to be bound by the theories, that the higher ratio of the H₂ gas to the NF₃ gas to (H₂ gas: NF₃ gas), the higher selectivity of the silicon oxide layer to the silicon nitride layer is obtained. Thus, by adjusting the ratio between the H₂ gas to the NF₃ gas, a desired selectivity between the silicon oxide layer to the silicon nitride layer may be obtained as needed.

FIG. 6 is a flow diagram of another example of a method 600 for manufacturing nanowire spacers in nanowire structures (e.g., channel structures) with composite materials for horizontal gate-all-around (hGAA) semiconductor device structures. FIGS. 7A-7D₂ are cross-sectional views of a portion of a composite substrate corresponding to various stages of the method 600. Similarly, the method 600 may be utilized to form the nanowire spacers in nanowire structures for horizontal gate-all-around (hGAA) semiconductor devices on a substrate. Alternatively, the method 600 may be beneficially utilized to manufacture other types of structures. It is noted that the resultant structure as utilized here depicted in FIG. 7A-7D₂ may be similar to the resultant structure depicted in FIG. 5A-5F.

The method 600 begins at operation 602 by providing a substrate, such as the substrate 502 depicted in FIG. 1 and FIG. 5A, having the film stack 501 formed thereon, as shown in FIG. 7A. The operation 602 and 604 described here is similar to the operation 402 and 404 depicted in FIG. 4. After the lateral etching process at operation 604, the recess 516 is defined in the multi-material layer 512 with the recess inner sidewall 532, as depicted in FIG. 7B. Subsequently, similar to the operation 406, a liner fill process may be performed at operation 606 to fill a liner layer 702 in the recess 516 defined in the multi-material layer 512. As the liner layer 702 in operation 606 is required to be filled within the recess 516, the process selected to perform the liner fill process may utilize certain liquid-type precursor that may be leveraged or reflowed into the recess 516 for deposition. For example, a liquid based deposition process, such as a flowable CVD process or a spin-on deposition process, may be utilized. Other suitable deposition process include a cyclical layer deposition (CLD), an atomic layer deposition (ALD), a plasma enhanced chemical vapor deposition (PE CVD), a physical vapor deposition (PVD) or any suitable deposition process to fill the liner layer 702 in the structure of the multi-material layer 512, including the recess 516 defined therein. Similarly, the liner layer 702 may be filled in the multi-material layer 512 on the substrate 502 with a sufficient thickness to fill in the recess 516 as well as the open areas in the multi-material layer 512, including a depth 525 (e.g., the total thickness shown in FIGS. 5D₁ and 5D₂) of the multi-material layer 512, as shown in FIG. 7C.

In one example, the flowable CVD process is utilized to perform the liner fill deposition process in a flowable CVD processing chamber such as the processing chamber depicted in FIG. 2. The liner fill deposition process performed in the deposition chamber 200 is a flowable CVD process that forms the liner layer 702 as a polysilazanes based silicon containing film (PSZ-like film), which may be reflowable and fillable within trenches, features, vias, recess or other apertures defined in a substrate where the polysilazanes based silicon containing film is deposited.

As the liner layer 702 will later be utilized to form nanowire spacer structures, the material of the liner layer 702 as formed is selected to be a silicon containing material that may reduce parasitic capacitance between the fate and source/drain structure in the hGAA nanowire structure, such as a low-K material, a silicon containing material, such as silicon nitride, silicon oxide, silicon oxynitride, silicon carbide, silicon oxycarbide, silicon carbide nitride, or other suitable materials, such as Black Diamond® material available from Applied Materials.

In one embodiment, the liner layer 702 is a low-k material (e.g., dielectric constant less than 4) or a silicon oxide/silicon nitride/silicon carbide containing material with a sufficient width 708 formed in the recess 516.

At operation 608 and 610, after the liner layer 702 is filled in the recess, an etching process (an isotropic etching process at operation 610 or an un-isotropic etching process at operation 608) may be performed to etch the redundant liner layer 702 (e.g., the liner layer 702 formed over the recess 516), as shown in FIGS. 7D₁ and 7D₂, leaving primarily the liner layer 702 in the recess 516 defined in the multi-material layer 512, which may be utilized to form as nanowire spacers after the device structure is completed, particularly for the hGAA device structure.

The etching process at operation 610 and 680 (either isotropic etching process or un-isotropic etching process) may be continuously performed to etch through the liner layer 702 overfilled from the multi-material layer 512 (e.g., from the sidewall 518 from the first layer 512a of the multi-material layer 512) so as to leave the liner layer 702 predominately filling in the recess 516, forming a recess outer sidewall 704, 706 (in FIGS. 7D₁ and 7D₂ respectively after an isotropic etching at operation 610 or an un-isotropic etch at operation 608) substantially aligned with the sidewall 518 from the first layer 512a of the multi-material layer 512. As the isotropic etching process at operation 610 is performed utilizing etchants without any specific directionality, the etchants tends to attack the liner layer 702 universally, thus, creating a relatively round, curved or non-straight recess outer sidewall 704, as shown in FIG. 7D₁. In contrast, as the un-isotropic etching process at operation 608 is performed utilizing etchants with specific directionality, such as vertically toward substrate surface during etching, the etchants tends to attack the liner layer 702 with specific vertical direction, thus, creating a relatively straight, flat, and even recess outer sidewall 706, as shown in FIG. 7D₂. It is noted that both etching process at operation 608 and 610 may be utilized based on different process and device structure requirements.

It is noted that the un-isotropic etching process at operation 608 may be similar to the main etching process at operation 408 described above. For the isotropic etching process at operation 610, a RF bias power may be eliminated during the isotropic etching process so as to make the etchants distribute randomly, universally, or isotopically across the substrate surface.

FIG. 8 is a flow diagram of another example of a method 800 for manufacturing nanowire spacers in nanowire structures (e.g., channel structures) with composite materials for horizontal gate-all-around (hGAA) semiconductor device structures. FIGS. 9A-9C are cross-sectional views of a portion of a composite substrate corresponding to various stages of the method 800. Similarly, the method 800 may be utilized to form the nanowire spacers in nanowire structures for horizontal gate-all-around (hGAA) semiconductor devices on a substrate. Alternatively, the method 800 may be beneficially utilized to manufacture other types of structures. It is noted that the resultant structure as utilized here depicted in FIG. 9A-9C may be similar to the resultant structure depicted in FIGS. 5A-5F or FIGS. 7A-7D₂.

The method 800 begins at operation 802 by continuing the process at the operation 412, after performing the liner removal process at operation 412 with a resultant structure shown in FIG. 5F. Thus, the structure depicted FIG. 9A is a replica of the structure of FIG. 5F for ease of explanation for the method 800 depicted in FIG. 8. As discussed earlier, the structure of FIG. 9A (the same as the structure of FIG. 5F) includes the dielectric layer 524 filled in the recess 516 defined in the multi-material layer 512, defining the recess outer sidewall 530 substantially aligned with the sidewall 518 of the first layer 512a of the multi-material layer 512.

At operation 804, a dielectric fill removal processing is performed to remove the dielectric layer 524 from the recess 516, leaving the liner layer 523 exposed in the recess 516 defined in the multi-material layer 512, as shown in FIG. 9B. As the dielectric layer 524 is configured to be removed in this particular example, thus, the quality requirement of this dielectric layer 524 utilized for the method 800 may not be as high as the dielectric layer 524 required for the method 400 described above. For example, the dielectric layer 524, configured to be employed in the example depicted in FIGS. 9A-9C for method 800, may be a dummy material (e.g., low-quality dielectric layer), such as an organic polymer layer, an amorphous carbon layer, a silicon oxide layer manufactured with low cost process, such as a spin-on coating process or any suitable low temperature process. In one particular example depicted in FIGS. 9A-9C for method 800, the dielectric layer 524 is an amorphous carbon layer.

In one example, the dielectric fill removal process may be an etching process, an ash process, or a strip process that may easily remove the dielectric layer 524 from the substrate. In the example wherein the dielectric layer 524 is an amorphous carbon layer depicted in FIG. 9A, the ash or strip process as performed at operation 804 may utilize an oxygen containing gas. Alternatively, any suitable etching process, including dry or wet etching process, such as a reactive ion etching process, may also be utilized to selectively remove the dielectric layer 524 from the substrate 502 without damaging the liner layer 523 or other portions of the substrate 502 as needed.

At operation 806, after the dielectric layer 524 is removed, an epitaxial deposition process is performed to selectively grow an epi-silicon layer 902 from the first layer 512a of the multi-material layer 512, as shown in FIG. 9C. As the first layer 512a in this example is selected to fabricate from a intrinsic silicon material, the epitaxial deposition process as performed at operation 806 may grow from the sidewall 518 of the first layer 512a (e.g., a silicon compatible material) rather than the liner layer 523 (e.g., a silicon dielectric layer or the like rather than an intrinsic silicon material) exposed in the recess 516. The epi-silicon layer 902 grown from the sidewall 518 of the first layer 512a only include a tip part 906 slightly protruding toward the recess 516 defined in the multi-material layer 512, thus forming an air gap 904 in the recess 516 occupying most of the space in the recess 516 except the area occupied by the tip part 906. The air gap 904 formed in the recess 516 may later be utilized to form the nanowire spacer (e.g., an air gap spacer) for nanowire structures for horizontal gate-all-around (hGAA) semiconductor devices on a substrate.

FIG. 10 is a flow diagram of another example of a method 1000 for manufacturing nanowire spacers in nanowire structures (e.g., channel structures) with composite materials for horizontal gate-all-around (hGAA) semiconductor device structures. FIGS. 11A-11D are cross-sectional views of a portion of a composite substrate corresponding to various stages of the method 1000. Similarly, the method 1000 may be utilized to form the nanowire spacers in nanowire structures for horizontal gate-all-around (hGAA) semiconductor devices on a substrate. Alternatively, the method 1000 may be beneficially utilized to manufacture other types of structures. It is noted that the resultant structure as utilized here depicted in FIG. 11A-11D may be similar to the resultant structure depicted in FIGS. 5A-5F or FIGS. 7A-7D₂ or FIGS. 9A-9C.

The method 1000 begins at operation 1002 by continuing the process at the operation 405, after performing the liner layer deposition process at operation 405 with a resultant structure shown in FIG. 5C. Thus, the structure depicted FIG. 11A is a replica of the structure of FIG. 5C for ease of explanation for the method 1000 depicted in FIG. 10. As discussed earlier, the structure of FIG. 11A (the same as the structure of FIG. 5C) includes the liner layer 523 covering the surfaces of the multi-material layer 512 as well as the substrate 502. The liner layer 523 may provide an interface protection with a good interface adhesion and planarity for the materials formed thereon with good uniformity, conformity, adhesion and planarity.

At operation 1004, an oxidation treatment process is performed to predominately treat the liner layer 523 on the sidewall 518 of the first layer 512a, forming a liner modification region 1102 primarily located on the sidewall 518 of the first layer 512a, as shown in FIG. 11B. The liner layer 523 located within the inner surface of the recess 516 and/or on sidewall 522 of the second layer 512b is remained un-modified/unchanged as the liner layer is substantially shielded by the first layer 512a from the multi-material layer 512. By selective oxidation treatment, only a portion of the liner layer 523 is treated converting to the liner modification region 1102, which may be later easily removed from the substrate 502 by a selective etching process.

In one example, the oxidation treatment process is performed by selectively treating the located predominately on the sidewall 518 of the first layer 512a, The oxidation treatment process may be any suitable plasma process with oxygen species. Suitable examples of the oxygen species may be from a plasma formed from an oxygen containing gas, such as O₂, H₂O, H₂O₂ and O₃, as needed.

In one implementation, the oxidation treatment process may be performed in a plasma containing environment (such as decoupled plasma oxidation or rapid thermal oxidation), a thermal environment (such as furnace) or thermal plasma environment (such as APCVD, SACVD, LPCVD, or any suitable CVD processes). The oxidation treatment process may be performed by using an oxygen containing gas mixture in a processing environment to react the liner layer 523 predominately on the sidewall 518 of the first layer 512a. In one implementation, the oxygen containing gas mixture includes at least one of an oxygen containing gas with or without an inert gas. Suitable examples of the oxygen containing gas include O₂, O₃, H₂O, NO₂, N₂O, steam vapor, moisture and the like. Suitable examples of the inert gas supplied with the gas mixture include at least one of Ar, He, Kr, and the like. In an exemplary embodiment, the oxygen containing gas supplied in the oxygen containing gas mixture is O₂ gas.

During the oxidation treatment process, several process parameters may be regulated to control the oxidation process. In one exemplary implementation, a process pressure is regulated between about 0.1 Torr and about atmosphere (e.g., 760 Torr). In one example, the oxidation process as performed at operation 304 is configured to have a relatively high deposition pressure, such as a pressure greater than 100 Torr, such as between about 300 Torr and atmosphere. Suitable techniques that may be utilized to perform the selective oxidation treatment process at operation 1004 may include decoupled plasma oxide process (DPO), plasma enhanced chemical vapor deposition process (PECVD), low pressure chemical vapor deposition process (LPCVD), sub-atmospheric chemical vapor deposition process (SACVD), atmospheric chemical vapor deposition process (APCVD), thermal furnace process, oxygen annealing process, plasma immersion process, or any suitable process as needed. In one implementation, the oxidation process can be performed under ultra-violet (UV) light illumination.

At operation 1006, a selective liner removal process is performed to selectively remove the liner modification region 1102 from the substrate 502, only leaving a portion of the liner layer 523 remained in the recess 516 of the multi-material layer 512, as shown in FIG. 11C. As the liner modification region 1102 is removed from the substrate 502, the sidewall 518 of the first layer 512a is exposed. The selectively liner removal process may be any suitable etching process, including wet etching or dry etching, as needed, that may provide high selectivity to predominately remove the liner modification region 1102 without attacking the liner layer 523 remained on the substrate 502.

At operation 1008, similar to the operation 806, an epitaxial deposition process is performed to selectively grow an epi-silicon layer 1104 from the first layer 512a of the multi-material layer 512, as shown in FIG. 11D. As the first layer 512a in this example is selected to fabricate from an intrinsic silicon material and is exposed after the selective liner removal process at operation 1006, the epitaxial deposition process as performed at operation 1008 may grow from the sidewall 518 of the first layer 512a (e.g., a silicon compatible material) rather than the remaining liner layer 523 (e.g., a silicon dielectric layer or the like rather than an intrinsic silicon material) in the recess 516. The epi-silicon layer 1104 grown from the sidewall 518 of the first layer 512a only include a tip part 1106 slightly protruding toward the recess 516 defined in the multi-material layer 512, thus forming an air gap 1108 in the recess 516 occupying most of the space in the recess 516 except the area occupied by the tip part 1106. The air gap 1108 formed in the recess 516 may later be utilized to form the nanowire spacer (e.g., an air gap spacer) for nanowire structures for horizontal gate-all-around (hGAA) semiconductor devices on a substrate.

In yet another example, when an air gap is desired to be formed in the recess 516, after the liner 523 is formed on the substrate in FIG. 11A at operation 1002 (or from FIG. 5C at operation 405), the process may be skipped and leaped to the operation 1006 to selectively remove the liner layer 523 formed predominately on the sidewall 518 of the first layer 512a, as shown in FIG. 11C. By doing so, the dummy dielectric layer formation process at operation 802 or the oxidation treatment process at operation 1004 may be eliminated to save manufacturing cost. Subsequently, an epitaxial deposition process, similar to the operation 1008 and 806 is performed to selectively grow an epi-silicon layer 1104 from the first layer 512a of the multi-material layer 512, as shown in FIG. 11D.

FIG. 12 depicts a schematic view of the multi-material layer 512 having pairs of the first layer 512a and the second layer 512b with a nanowire spacer 1202 formed therein utilized in a horizontal gate-all-around (hGAA) structure 1200. The horizontal gate-all-around (hGAA) structure 1200 utilizes the multi-material layer 512 as nanowires (e.g., channels) between source/drain anchors 1206 (also shown as 1206a, 1206b for source and drain anchors, respectively) and a gate structure 1204. As shown in the cross-sectional view of the multi-material layer 512 in FIG. 12, the nanowire spacer 1202 (such as the dielectric layer 524, 702 depicted in FIGS. 5E₁, 7D₁ and 7D₂, or the air gap 904, 1108 depicted in FIGS. 9C and 11D) formed at the bottom (e.g., or an end) of the second layer 512b may assist managing the interface wherein the second layer 512b is in contact with the gate structure 1204 and/or the source/drain anchors 1206a, 1206b so as to reduce parasitic capacitance and maintain minimum device leakage.

Thus, methods for forming nanowire structures with reduced parasitic capacitance and minimum device leakage for horizontal gate-all-around (hGAA) structures are provided. The methods utilize dielectric layers or air gaps to form as nanowire spacers in nanowire structures with reduced parasitic capacitance and minimum device leakage at the interface that may be later utilized to form horizontal gate-all-around (hGAA) structures. Thus, horizontal gate-all-around (hGAA) structures with desired type of material and device electrical performance may be obtained, particularly for applications in horizontal gate-all-around field effect transistors (hGAA FET).

While the foregoing is directed to embodiments of the present invention, other and further embodiments of the invention may be devised without departing from the basic scope thereof, and the scope thereof is determined by the claims that follow.

1. A method of forming nanowire spaces for nanowire structures on a substrate comprising:
performing a lateral etching process on a substrate having a multi-material layer disposed thereon, wherein the multi-material layer including repeating pairs of a first layer and a second layer, the first and second layers each having a first sidewall and a second sidewall respectively exposed in the multi-material layer, wherein the lateral etching process predominately etches the second layer through the second layer forming a recess in the second layer;
filling the recess with a dielectric material; and
removing the dielectric layer extending out of the recess.

2. The method of claim 1, further comprising:
forming a liner layer in the recess prior to filling the dielectric material in the recess.

3. The method of claim 2, further comprising:
removing the liner layer formed on the first sidewall of the first layer prior to filling the dielectric layer in the recess.

4. The method of claim 2, where the liner layer includes more than one layer.

5. The method of claim 2, wherein the liner layer is silicon nitride, silicon oxynitride, silicon oxycarbide, silicon carbonitride or silicon oxycarbonitride or silicon materials with dopants.

6. The method of claim 2, wherein the liner layer is fabricated by an ALD process.

7. The method of claim 2, wherein the liner layer has a thickness between about 0.5 nm and about 5 nm.

8. The method of claim 1, wherein the first layer of the multi-material layer is an intrinsic silicon layer and the second layer of the multi-material layer is a SiGe layer while the substrate is a silicon substrate.

9. The method of claim 1, further comprising:
forming the dielectric layer in the recess as an nanowire spacer in horizontal gate-all-around (hGAA) structures.

10. The method of claim 1, wherein the dielectric layer is selected from a group consisting of silicon nitride, silicon oxide, silicon oxynitride, silicon carbide, silicon oxycarbide, silicon carbide nitride and doped silicon layer.

11. The method of claim 1, wherein filling the recess with the dielectric material comprises:
filling an amorphous carbon from the substrate.

12. The method of claim 1, wherein removing the dielectric layer further comprises:
etching the dielectric layer filled over the recess by an isotropic etching process or by an anisotropic etching process.

13. The method of claim 3, further comprising:
forming an epi-silicon layer from the first sidewall of the first layer in the multi-material layer.

14. The method of claim 13, further comprising:
forming an air gap in the recess.

15. The method of claim 14, further comprising:
forming the air gap in the recess as an nanowire air gap spacer in horizontal gate-all-around (hGAA) structures.

16. The method of claim 3, further comprising:
performing an oxide treatment process on the liner layer to form an oxidation modification layer predominately formed on the first sidewall of the first layer.

17. The method of claim 16, further comprising:
maintaining the liner layer within the recess unchanged from the oxide treatment process.

18. The method of claim 17, further comprising:
selectively removing the oxidation modification layer from the first sidewall of the first layer while maintaining the liner layer remained in the recess.

19. The method of claim 18, further comprising
forming an epi-silicon layer from the first sidewall of the first layer in the multi-material layer.

20. The method of claim 19, further comprising:
forming an air gap in the recess.
